(19) United States
(12) Patent Application Publication
(10) Pub. No.: US 2025/0300026 A1
(43) Pub. Date: Sep. 25, 2025

(54) SEMICONDUCTOR DEVICE AND WIRING BOARD

(71) Applicant: AOI ELECTRONICS CO., LTD., Takamatsu-shi, Kagawa (JP)

(72) Inventors: Shinji WAKISAKA, Tokyo (JP); Masato FUKUSHIMA, Tokyo (JP); Takayuki HIROISHI, Tokyo (JP); Ichiro MIHARA, Tokyo (JP); Tomoyuki KOSUGI, Tokyo (JP)

(21) Appl. No.: 18/710,307

(22) PCT Filed: Aug. 31, 2022
(86) PCT No.: PCT/JP2022/032853

§ 371 Date: Oct. 31, 2024

(30) Foreign Application Priority Data
Nov. 16, 2021 (JP) 2021-186390

(51) Int. Cl. H01L 21/66; G01K 7/16; H01L 23/00; H01L 23/31; H01L 23/498

(52) U.S. Cl. CPC H01L 22/34; G01K 7/16; H01L 23/3128; H01L 23/49816; H01L 23/49822; H01L 24/11; H01L 24/13; H01L 24/16; H01L 2224/1132; H01L 2224/11462; H01L 2224/11849; H01L 2224/13024; H01L 2224/16227

(57) ABSTRACT

A substrate 10 has an integrated circuit formed therein and has a pad electrode PD formed on an upper surface thereof and electrically connected to the integrated circuit. An insulating film IF2 is formed on the upper surface of the substrate 10, and an opening OP is formed in the insulating film IF2. A redistribution wiring PW1 is formed in the opening OP and on the insulating film IF2 and is electrically connected to the pad electrode PD. An external connection terminal ET1 electrically connected to the redistribution wiring RW1 is formed on the redistribution wiring RW1. Also, a redistribution wiring RW2 is formed on the insulating film IF2 and is electrically isolated from the redistribution wiring RW1, the pad electrode PD, and the integrated circuit. A plurality of external connection terminals ET2 electrically connected to the redistribution wiring RW2 are formed on the redistribution wiring RW2. The redistribution wiring RW2 and the external connection terminal ET2 constitute a measuring circuit (20) for measuring a resistance value.

### CROSS-REFERENCE TO RELATED APPLICATIONS

This application is a National Stage application of International Patent Application No. PCT/JP2022/032853, filed on Aug. 31, 2022, which claims priority to Japanese Patent Application No. 2021-186390, filed on Nov. 16, 2021, each of which is hereby incorporated by reference in its entirety.

### TECHNICAL FIELD

The present invention relates to a semiconductor device and a wiring board.

### BACKGROUND

In recent years, due to demands for faster operation and size reduction of semiconductor devices, a technique of forming a wiring referred to as a redistribution wiring on a pad electrode, which is a part of a wiring of an uppermost layer of a multi-layer wiring layer on a semiconductor substrate, has been developed. The redistribution wiring is made of a material mainly made of copper and is formed by, for example, the plating method in order to reduce the wiring resistance. External connection terminals such as bump electrodes, solder balls, or wire bonding are formed on a part of an upper surface of the redistribution wiring. In a semiconductor device in which the redistribution wiring is adopted, the external connection terminals can be arranged in a region different from the pad electrodes by laying out the redistribution wiring.

Patent Document 1 discloses a semiconductor device referred to as WLCSP (Wafer Level Chip Size Package). In Patent Document 1, a redistribution wiring is formed on a pad electrode electrically connected to an integrated circuit. A ball electrode made of solder is formed on the redistribution wiring, and the redistribution wiring is sealed with a resin film.

Patent Document 2 discloses a semiconductor chip for evaluating electromigration. A multilayer wiring pattern for evaluating electromigration is formed of vias made of tungsten and wirings made of aluminum or vias made of copper and wirings made of copper. A measurement system to evaluate each wiring by accelerating electromigration using Joule heating of the multilayer wiring pattern has been devised. Namely, the semiconductor chip of Patent Document 2 does not include an integrated circuit that functions as an actual product, but includes only a dedicated circuit for evaluating electromigration.

Patent Document 3 and Patent Document 4 disclose temperature measuring circuits composed of semiconductor elements. Bipolar transistors are used as the semiconductor elements, and a differential circuit composed mainly of bipolar transistors constitutes a circuit for measuring the increase in resistance value due to temperature rise.
Patent Document 1: Japanese Unexamined Patent Application Publication No. 2003-188313
Patent Document 2: Japanese Patent No. 4148911
Patent Document 3: Japanese Unexamined Patent Application Publication No. 2009-145070
Patent Document 4: Japanese Patent No. 5144559

### SUMMARY

### Problems to be Solved by the Invention

In recent years, in semiconductor devices such as a high-performance processor, a power management IC, a DC-DC converter, and a power supply IC, heat generated from the semiconductor device itself has become a problem. If it were possible to measure the temperature generated from the semiconductor device itself when such a semiconductor device is actually used, it would be beneficial for temperature management or control, but the conventional arts have the following problems.

For example, in Patent Document 1, the semiconductor device itself is not provided with a function of measuring temperature. Therefore, a method of measuring temperature by attaching a thermometer such as a thermocouple to the semiconductor device is assumed. In that case, there is a problem that only the temperature outside the semiconductor device can be measured. In addition, there is also a problem that it is necessary to secure a space for attaching the thermometer. Further, the method using attached thermometer is not suitable for mass production because of the difficulty in batch process and automation.

In addition, Patent Document 2 is an evaluation chip provided with a dedicated circuit for evaluating electromigration. Therefore, it is not possible to measure the temperature of a semiconductor device when the semiconductor device shipped as a product is actually used. In addition, it is impractical to provide such a dedicated circuit inside the semiconductor device because it would cause the circuit to be complicated or the chip size to increase.

In Patent Document 3 and Patent Document 4 as well, providing a temperature measuring circuit inside the semiconductor device would cause the circuit to be complicated or the chip size to increase. In addition, since the circuit is configured of bipolar transistors, it is difficult to apply such a circuit unless it is compatible with the semiconductor process.

Considering the above, there is a need for a technique capable of providing a circuit for temperature measurement in the semiconductor device to be shipped as a product without increasing the size of the semiconductor chip and without increasing the size of the package. Namely, a technique capable of improving the reliability of the semiconductor device without hindering the miniaturization of the semiconductor device is desired. Furthermore, if these techniques can be realized without the addition of special parts or special manufacturing processes, it will be possible to reduce the manufacturing cost of the semiconductor device.

Other problems and novel features will become apparent from the description of this specification and the accompanying drawings.

### Means for Solving the Problem

An outline of a typical embodiment disclosed in this application will be briefly described as follows.

A semiconductor device according to an embodiment includes: a substrate having an integrated circuit formed therein and having a pad electrode formed on an upper surface thereof and electrically connected to the integrated circuit; an insulating film formed on the upper surface of the substrate so as to cover the pad electrode; an opening formed in the insulating film so as to reach an upper surface of the pad electrode; a first redistribution wiring formed in the opening and on the insulating film and electrically connected to the pad electrode; a first external connection terminal formed on the first redistribution wiring and electrically connected to the first redistribution wiring; a second redistribution wiring formed on the insulating film and electrically isolated from the first redistribution wiring, the pad electrode, and the integrated circuit; and a plurality of second external connection terminals formed on the second redistribution wiring and electrically connected to the second redistribution wiring. Here, the second redistribution wiring and the plurality of second external connection terminals constitute a first measuring circuit for measuring a resistance value.

### Effects of the Invention

According to an embodiment, it is possible to improve the reliability of the semiconductor device without hindering the miniaturization of the semiconductor device.

### BRIEF DESCRIPTIONS OF THE DRAWINGS

FIG. 1 is a plan view showing a semiconductor device according to the first embodiment.

FIG. 2 is a cross-sectional view showing the semiconductor device according to the first embodiment.

FIG. 3 is an equivalent circuit diagram when measuring a resistance value of a resistance value measuring portion according to the first embodiment.

FIG. 4 is a flowchart for creating data showing a correlation between a resistance value and a temperature.

FIG. 5 is a table of the data showing the correlation between a resistance value and a temperature.

FIG. 6 is a graph showing the correlation between a resistance value and a temperature.

FIG. 7 is a graph showing a temperature and a time when a wiring for generating Joule heat is heated.

FIG. 8 is a cross-sectional view showing a manufacturing process of the semiconductor device according to the first embodiment.

FIG. 9 is a cross-sectional view showing the manufacturing process of the semiconductor device subsequent to FIG. 8.

FIG. 10 is a cross-sectional view showing the manufacturing process of the semiconductor device subsequent to FIG. 9.

FIG. 11 is a cross-sectional view showing the manufacturing process of the semiconductor device subsequent to FIG. 10.

FIG. 12 is a cross-sectional view showing the manufacturing process of the semiconductor device subsequent to FIG. 11.

FIG. 13 is a cross-sectional view showing the manufacturing process of the semiconductor device subsequent to FIG. 12.

FIG. 14 is a cross-sectional view showing the manufacturing process of the semiconductor device subsequent to FIG. 13.

FIG. 15 is a cross-sectional view showing the manufacturing process of the semiconductor device subsequent to FIG. 14.

FIG. 16 is a cross-sectional view showing the manufacturing process of the semiconductor device subsequent to FIG. 15.

FIG. 17 is a cross-sectional view showing the manufacturing process of the semiconductor device subsequent to FIG. 16.

FIG. 18 is a cross-sectional view showing a semiconductor device according to the second embodiment.

FIG. 19 is a cross-sectional view showing a mounting example of the semiconductor device according to the second embodiment.

FIG. 20 is a cross-sectional view showing a mounting example of a semiconductor device according to the first modification.

FIG. 21 is a cross-sectional view showing a mounting example of a semiconductor device according to the second modification.

FIG. 22 is an equivalent circuit diagram when measuring a resistance value of a resistance value measuring portion according to the second modification.

FIG. 23 is a cross-sectional view showing a semiconductor device according to the third embodiment.

### DETAILED DESCRIPTION

Hereinafter, embodiments will be described in detail with reference to drawings. Note that the members having the same function are denoted by the same reference characters throughout the drawings for describing the embodiments, and the repetitive description thereof will be omitted. Further, in the following embodiments, the description of the same or similar part will not be repeated in principle unless particularly required.

Also, the X direction, the Y direction, and the Z direction in the description of this application cross each other and are orthogonal to each other. In the description of this application, the Z direction is defined as the longitudinal direction, the height direction, or the thickness direction of a certain structure. Further, the expression “in plan view” or the like used in this application means that a plane configured by the X direction and the Y direction is seen in the Z direction.

### First Embodiment

### <Structure of Semiconductor Device>

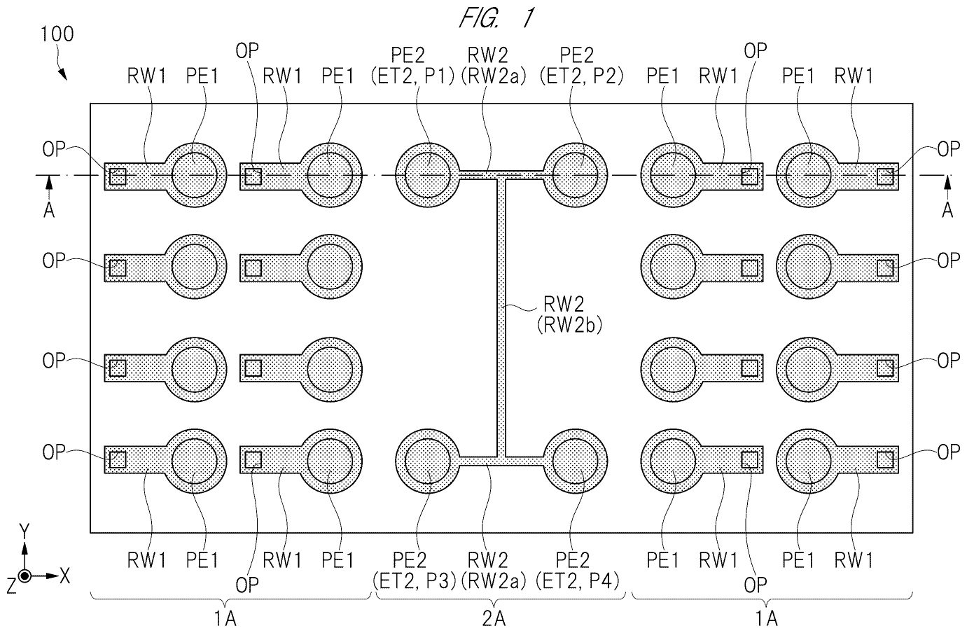

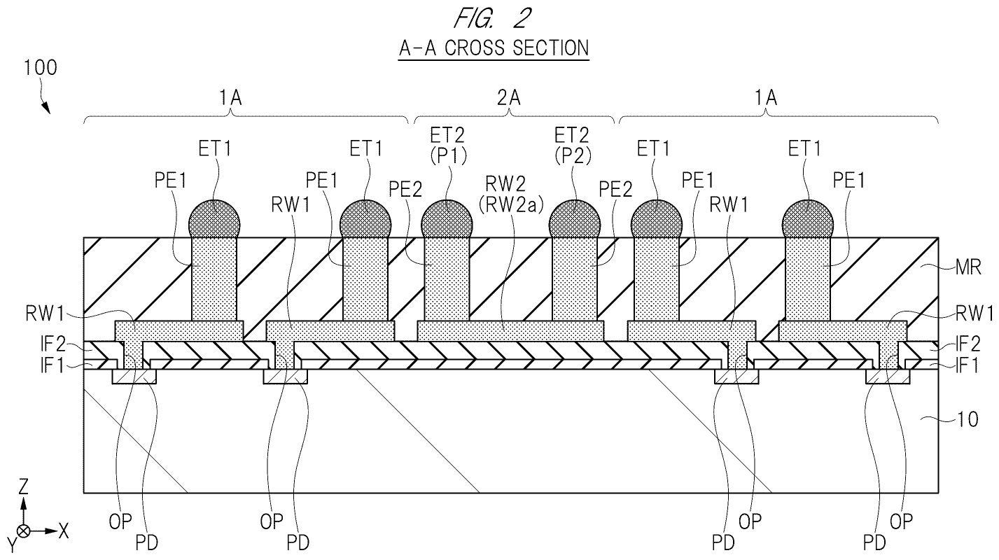

A semiconductor device 100 according to the first embodiment will be described below with reference to FIG. 1 and FIG. 2. FIG. 1 is a plan view showing a part of the semiconductor device 100, and FIG. 2 is a cross-sectional view taken along the line A-A in FIG. 1. The semiconductor device 100 is a semiconductor chip provided with redistribution wirings RW1 and RW2, columnar electrodes PE1 and PE2, and external connection terminals ET1 and ET2 above a substrate 10. Also, the mounting example of the semiconductor device 100 according to the first embodiment is WLCSP structure.

The substrate 10 has an integrated circuit formed therein. The integrated circuit is made up of a plurality of transistors formed on a semiconductor substrate made of silicon or the like and a multi-layer wiring layer formed on the semiconductor substrate. Further, the substrate 10 has a plurality of pad electrodes PD formed on an upper surface thereof, and has an insulating film IF1 covering the plurality of pad electrodes. The plurality of pad electrodes PD are a part of the wiring formed in the uppermost layer of the multi-layer wiring layer, and are portions of the wiring in the uppermost layer exposed from openings of the insulating film IF1. The plurality of pad electrodes PD include a conductive film mainly made of aluminum and has a thickness of, for example, 300 to 1000 nm. The insulating film IF1 is a protective film for preventing moisture from entering the inside of the substrate 10, is composed of, for example, a stacked film of a silicon nitride film and a silicon oxide film, and has a thickness of, for example, 300 to 800 nm.

As shown in FIG. 1 and FIG. 2, an insulating film IF2 covers the plurality of pad electrodes PD. The insulating film IF2 is, for example, a photosensitive polyimide film, and has a thickness of, for example, 3 to 10 μm. A plurality of openings OP are formed in the insulating film IF2 so as to reach upper surfaces of the plurality of pad electrodes PD.

The redistribution wiring RW1 is formed in the opening OP and on the insulating film IF2, and is electrically connected to the pad electrode PD. Although the semiconductor device 100 is provided with a plurality of redistribution wirings RW1, one redistribution wiring RW1 is connected to one pad electrode PD1 here. The redistribution wiring RW2 is formed on the insulating film IF2, and is electrically isolated from the redistribution wiring RW1, the pad electrode PD, and the integrated circuit mentioned above. The redistribution wiring RW1 and the redistribution wiring RW2 are formed in the same layer and have the same thickness, for example, 1 μm or more and 10 μm or less.

The columnar electrode PE1 having a thickness larger than that of the redistribution wiring RW1 is formed on the redistribution wiring RW1. A plurality of columnar electrodes PE2 each having a thickness larger than that of the redistribution wiring RW2 are formed on the redistribution wiring RW2. The columnar electrode PE1 and the columnar electrode PE2 are formed in the same layer and have the same thickness, for example, 10 μm or more and 50 μm or less. Note that the redistribution wiring RW1, the redistribution wiring RW2, the columnar electrode PE1, and the columnar electrode PE2 are made of a material having a sheet resistance value lower than that of the material constituting the pad electrode PD, and are made of, for example, a conductive material mainly made of copper.

A sealing resin MR that seals the redistribution wirings RW1 and RW2 and the columnar electrodes PE1 and PE2 is formed on the insulating film IF so as to expose upper surfaces of the columnar electrodes PE1 and PE2. The sealing resin MR is, for example, a non-photosensitive epoxy resin. An upper surface of the sealing resin MR is subjected to polishing process. Therefore, the upper surfaces of the columnar electrodes PEL and PE2 and the sealing resin MR are flattened and flush with each other.

The external connection terminal ET1 is formed on the upper surface of the columnar electrode PE1, and the external connection terminal ET2 is formed on the upper surface of the columnar electrode PE2. The external connection terminals ET1 and ET2 are provided for electrical connection to a semiconductor chip, a lead frame, or a wiring board different from the semiconductor device 100, and are made of a conductive material mainly made of solder such as a solder ball. In plan view, the columnar electrode PE1 is located in a region different from the opening OP. By laying out the redistribution wiring RW1, the external connection terminal ET1 can be provided at a position different from the pad electrode PD.

The pad electrode PD, the redistribution wiring RW1, the columnar electrode PE1, and the external connection terminal ET1 are electrically connected to each other, and the redistribution wiring RW2, the columnar electrode PE2, and the external connection terminal ET2 are electrically connected to each other. However, the redistribution wiring RW2, the columnar electrode PE2, and the external connection terminal ET2 are electrically isolated from the pad electrode PD, the redistribution wiring RW1, the columnar electrode PE1, and the external connection terminal ET1.

### <Measuring Circuit 20>

Incidentally, the semiconductor device 100 according to the first embodiment includes a region 1A and a region 2A. The region 1A is a wiring region for the integrated circuit of the substrate 10, and is a region in which the redistribution wiring RW1 is formed. The region 2A is a wiring region for measuring the temperature of the semiconductor device 100, and is a region in which the redistribution wiring RW2 is formed.

As shown in FIG. 1, the redistribution wiring RW2 includes two inter-terminal connection portions RW2a and a resistance value measuring portion RW2b that connects the two inter-terminal connection portions RW2a. Two external connection terminals ET2 among the plurality of external connection terminals ET2 are electrically connected to one inter-terminal connection portion RW2a and constitute a start terminal P1 and a start terminal P2. Other two external connection terminals ET2 among the plurality of external connection terminals ET2 are electrically connected to the other inter-terminal connection portion RW2a and constitute an end terminal P3 and an end terminal P4.

The redistribution wiring RW2, the plurality of columnar electrodes PE2, and the plurality of external connection terminals ET2 (start terminals P1 and P2, end terminals P3 and P4) described above constitute a measuring circuit 20. Also, in the first embodiment, the two inter-terminal connection portions RW2a and the plurality of columnar electrodes PE2 constitute electrical paths that connect the resistance value measuring portion RW2b and the start terminals P1 and P2 and connect the resistance value measuring portion RW2b and the end terminals P3 and P4.

By electrically connecting a resistance measuring device 30 to the start terminal P1, the start terminal P2, the end terminal P3, and the end terminal P4, a resistance value R₀ of the resistance value measuring portion RW2b can be measured. Then, a temperature of the resistance value measuring portion RW2b can be calculated from the measured resistance value R₀ of the resistance value measuring portion RW2b. The calculation method thereof will be described below.

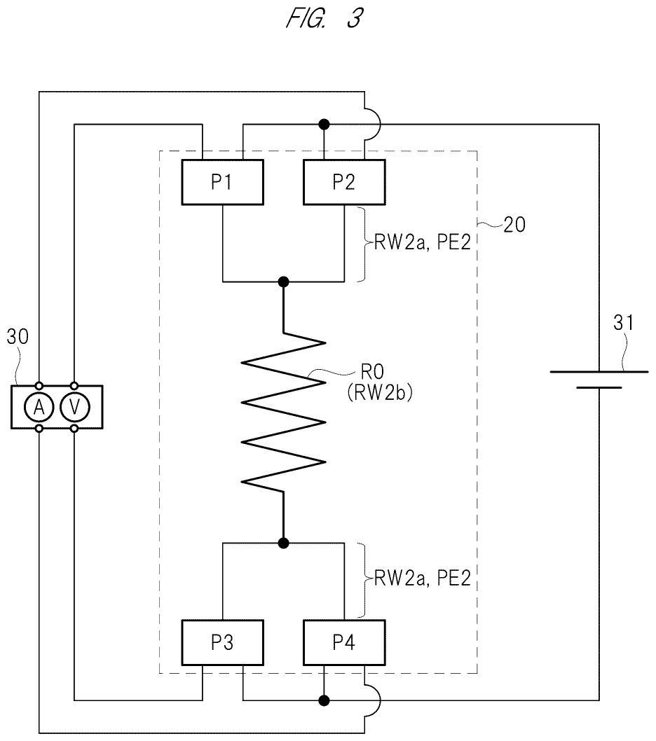

FIG. 3 is an equivalent circuit diagram when measuring the resistance value R₀ of the resistance value measuring portion RW2b. At the time of measurement, the resistance measuring device 30 and a DC power supply 31 are electrically connected to the start terminal P1, the start terminal P2, the end terminal P3, and the end terminal P4 of the measuring circuit 20. Since the measuring circuit 20 is a four-terminal circuit, only the resistance value R₀ of the resistance value measuring portion RW2b can be measured by eliminating a wiring length and contact resistance of the measuring circuit 20. Namely, the two inter-terminal connection portions RW2a and the plurality of columnar electrodes PE2 constitute electrical paths in the first embodiment, and only the resistance value R₀ of the resistance value measuring portion RW2b can be calculated by subtracting the resistance value of the electrical paths from the total resistance value.

When the resistance value between the start terminal P1 and the end terminal P3 is R₁₃, the resistance value between the start terminal P2 and the end terminal P4 is R₂₄, the resistance value between the start terminal P1 and the start terminal P2 is R₁₂, and the resistance value between the end terminal P3 and the end terminal P4 is R₃₄, the resistance value R₀ can be obtained by the following equation 1.

$${R}_{0} = \{ ( {R}_{13} + {R}_{24} ) - ( {R}_{12} + {R}_{34} ) \} / 2 \qquad Equation 1$$

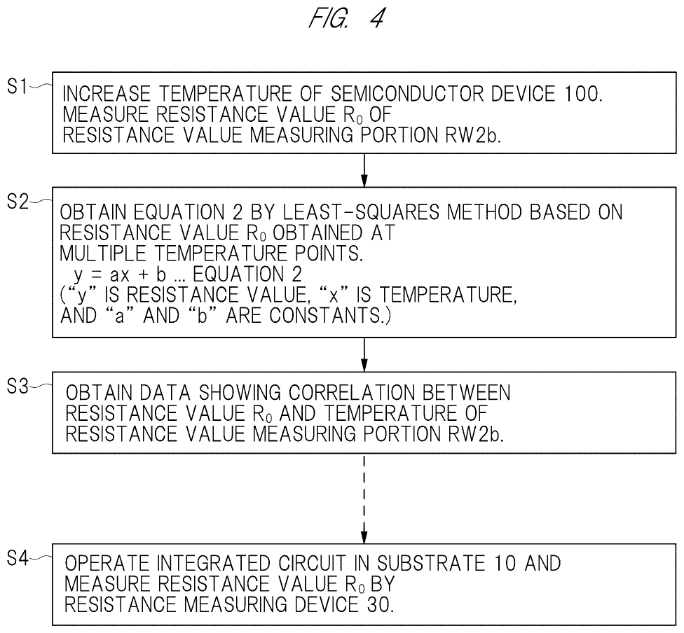

In order to calculate the temperature of the resistance value measuring portion RW2b from the resistance value R₀, the data showing the correlation between the resistance value R₀ and the temperature of the resistance value measuring portion RW2b is prepared in advance. FIG. 4 shows a flowchart for creating the data.

First, in step S1, the temperature of the semiconductor device 100 is increased by external heating. For example, with the semiconductor device 100 placed in a thermostatic oven, the resistance value R₀ of the resistance value measuring portion RW2b is measured as described above while increasing the temperature. At that time, the resistance value R₀ is measured by passing a current of a low current value (about 50 mmA) that causes no temperature rise due to Joule heat through the measuring circuit 20.

Next, in step S2, the following equation 2 is obtained by the least-squares method based on the resistance value R₀ obtained at multiple temperature points. Here, “y” is the resistance value, “x” is the temperature, and “a” and “b” are constants.

$$y = a x + b \qquad Equation 2$$

Next, in step S3, the data showing the correlation between the resistance value R₀ of the resistance value measuring portion RW2b and the temperature of the resistance value measuring portion RW2b is obtained by the above equation 2.

Step S4 is the process when the semiconductor device 100 is actually used. In step S4, the start terminal P1, the start terminal P2, the end terminal P3, and the end terminal P4 are connected to the resistance measuring device 30, the integrated circuit inside the substrate 10 is operated, and the resistance value R₀ is measured by the resistance measuring device 30. By referring to the data obtained in step S3, the temperature of the resistance value measuring portion RW2b can be calculated from the measured resistance value R₀.

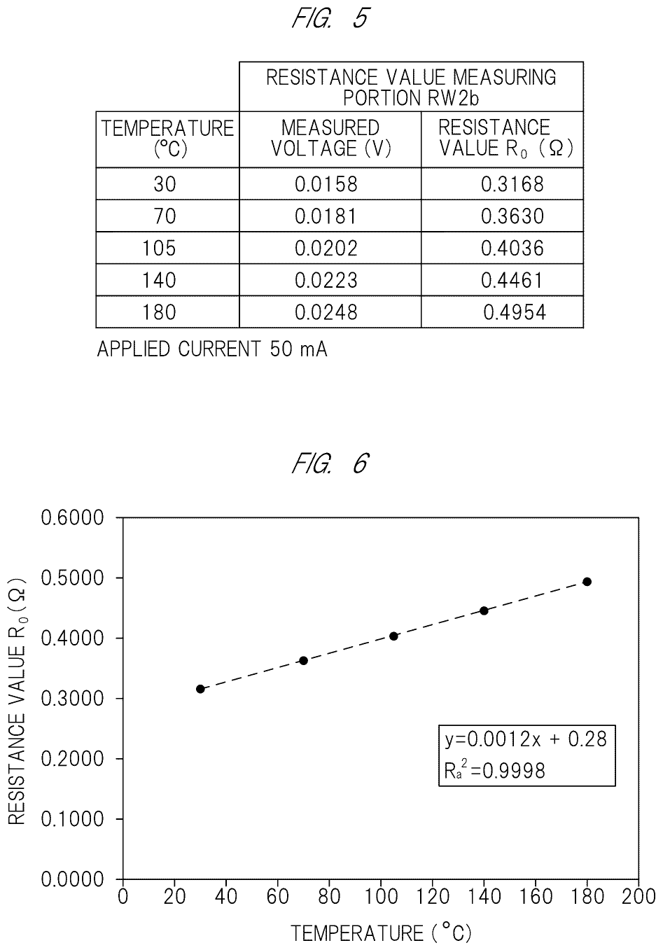

FIG. 5 to FIG. 7 are data showing the results of experiments conducted by the inventors of this application. FIG. 5 and FIG. 6 show the results obtained by step S3 in FIG. 4. FIG. 6 is a graph representing the data in FIG. 5. Here, the experiment was conducted with the resistance value measuring portion RW2b having a thickness of 5 μm, a width of 20 μm, and a length of 1.51 mm. The measuring circuit 20 was installed in a thermostatic oven, and a thermocouple was attached to measure the temperature. The applied current was a constant current of 50 mA.

As shown in FIG. 5, the temperature in the thermostatic oven was changed to 30° C., 70° C., 105° C., 140° C., and 180° C., the voltage at each temperature was measured, and the resistance value R₀ was calculated. As shown in FIG. 6, as a result of calculating the relational expression of the approximate straight line by the least squares method, the above equation 2 became “y=0.0012x+0.28” and the slope Ra² became 0.9998.

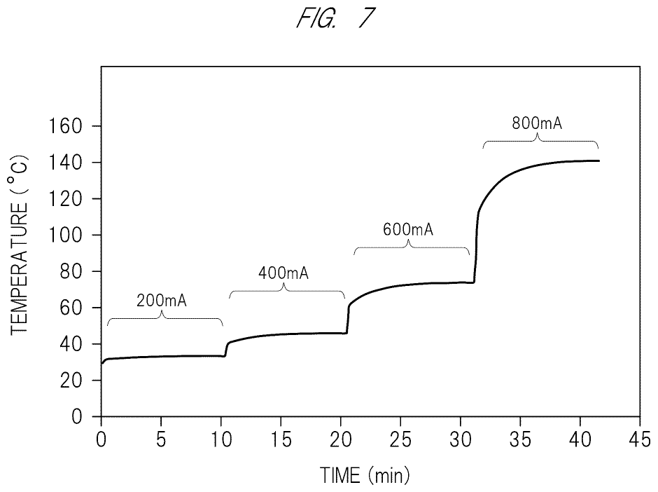

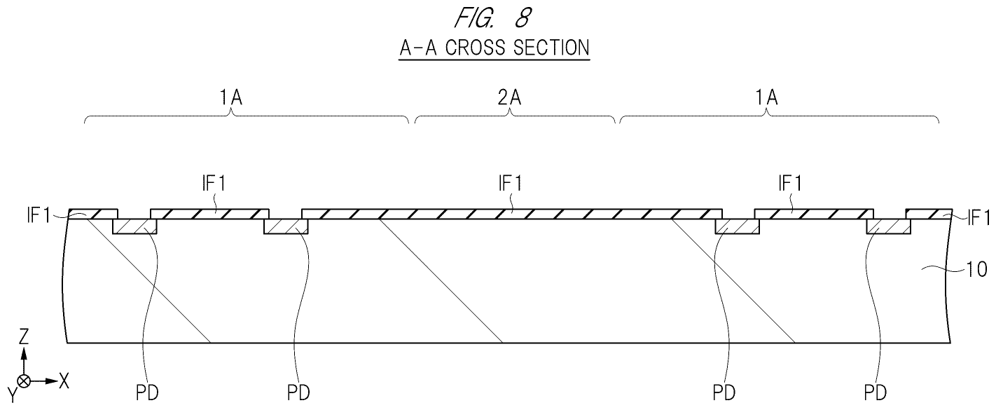

FIG. 7 shows the results of measuring the temperature from the resistance value measuring portion RW2b by providing a wiring for generating Joule heat in parallel with the resistance value measuring portion RW2b and generating the heat on the wiring for generating Joule heat. Note that the experiment was conducted with the wiring for generating Joule heat having a thickness of 5 μm, a width of 10 μm, and a length of 1.51 mm. Further, the distance between the resistance value measuring portion RW2b and the wiring for generating Joule heat was 20 μm.

Currents of 200 mA, 400 mA, 600 mA, and 800 mA were each applied to the wiring for generating Joule heat for 10 minutes. When the wiring for generating Joule heat was generating heat by applying the current, the resistance value R₀ of the adjacent resistance value measuring portion RW2b was measured using the equivalent circuit diagram in FIG. 3. The measured resistance value R0 was converted into the temperature by Equation 2 in FIG. 6, and the vertical axis in FIG. 7 represents the temperature. From the above, it was confirmed that the internal temperature of the semiconductor device 100 could be measured by the resistance value measuring portion RW2b.

As described above, according to the first embodiment, since the semiconductor device 100 is provided with the measuring circuit 20, the temperature of the resistance value measuring portion RW2b can be determined from the resistance value R₀ of the resistance value measuring portion RW2b. Therefore, the temperature inside the semiconductor device 100 can be known at the same time as the integrated circuit in the substrate 10 is operated. Namely, since the resistance value measuring portion RW2b is provided at a position very close to the surface of the substrate 10, the heat generated from the integrated circuit inside the substrate 10 can be measured more accurately. Therefore, the temperature management or control can be performed with high precision. Furthermore, by arranging the resistance value measuring portion RW2b above a location where heat generation is likely to occur, the temperature of the heat generating portion can be measured more accurately.

Also, the measuring circuit 20 can be provided without increasing the size of the substrate 10 and without increasing the size of the package. As described above, according to the first embodiment, the reliability of the semiconductor device can be improved without hindering the miniaturization of the semiconductor device.

Further, in the first embodiment, the case where one measuring circuit 20 is provided has been described as an example, but the semiconductor device 100 may be provided with two or more measuring circuits 20. In that case, it becomes possible to measure temperatures at different locations in the semiconductor device 100.

Furthermore, the measuring circuit 20 according to the first embodiment can be used also for an evaluation semiconductor device for evaluating each characteristic other than the case where the semiconductor device 100 is used as a product.

### <Method of Manufacturing Semiconductor Device>

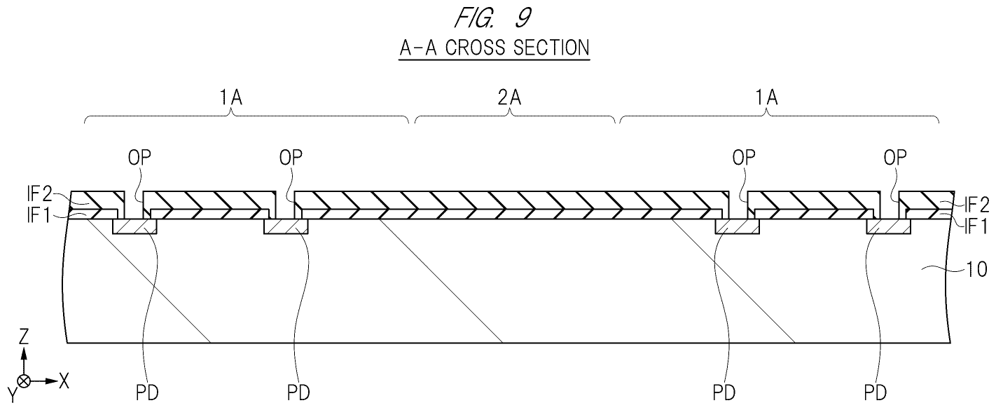

A method of manufacturing the semiconductor device according to the first embodiment will be described below with reference to FIG. 8 to FIG. 17.

First, as shown in FIG. 8, the substrate 10 provided with the integrated circuit and the pad electrode PD on the upper surface thereof is prepared. The upper surface of the substrate 10 is covered with the insulating film IF1, and the pad electrode PD is exposed in the opening of the insulating film IF.

As shown in FIG. 9, the insulating film IF2 is formed on the insulating film IF1 so as to cover the pad electrode PD. The insulating film IF2 is, for example, a photosensitive polyimide film and can be formed by, for example, the coating method. Next, the insulating film IF2 is patterned by selectively performing exposure process to the insulating film IF2. As a result, the opening OP reaching the upper surface of the pad electrode PD is formed in the insulating film IF2. Thereafter, the insulating film IF2 is hardened by performing heat treatment to the insulating film IF2.

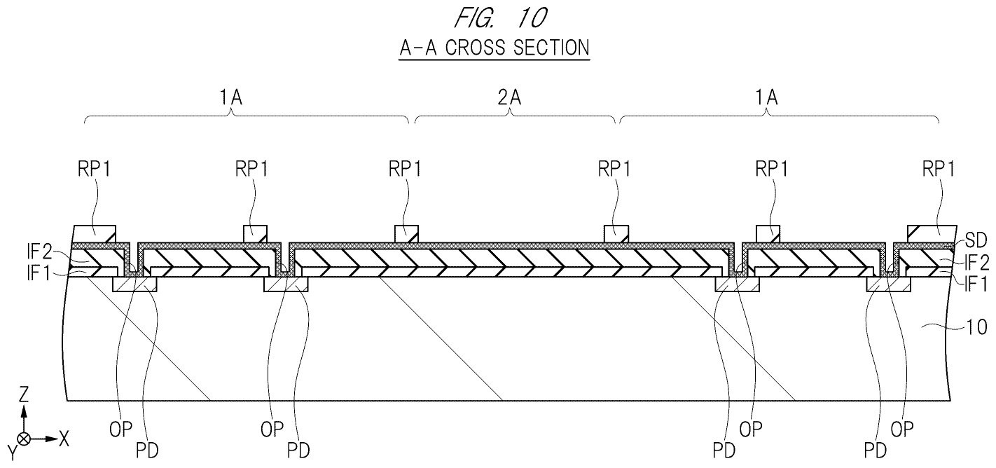

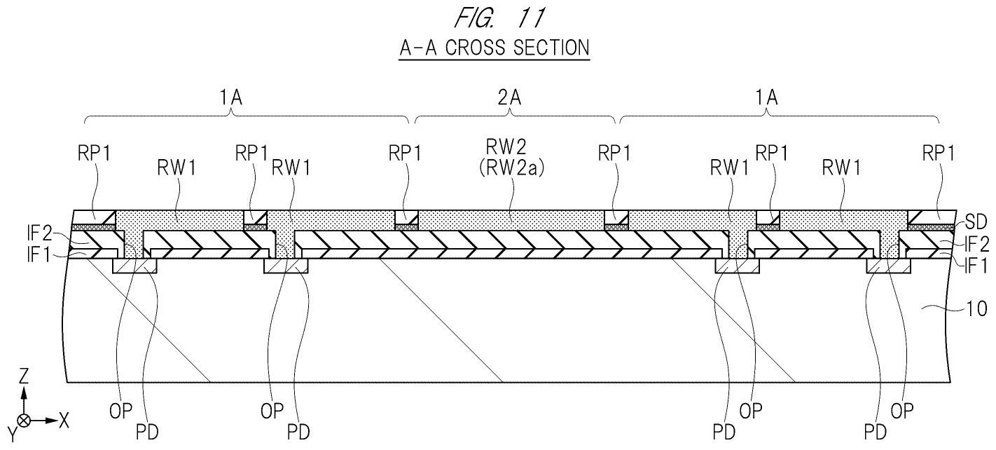

As shown in FIG. 10, a seed layer SD is formed in the opening OP and on the insulating film IF2 by the sputtering method. The seed layer SD is composed of, for example, a barrier metal film such as a titanium film and a copper film. Note that the thickness of the seed layer SD is about 200 to 800 nm. Next, a resist pattern RP1 having a pattern that opens at least the opening OP is formed on the insulating film IF2. The resist pattern RP1 is formed by forming a resist film by the coating method and patterning the resist film by selectively performing exposure process to the resist film.

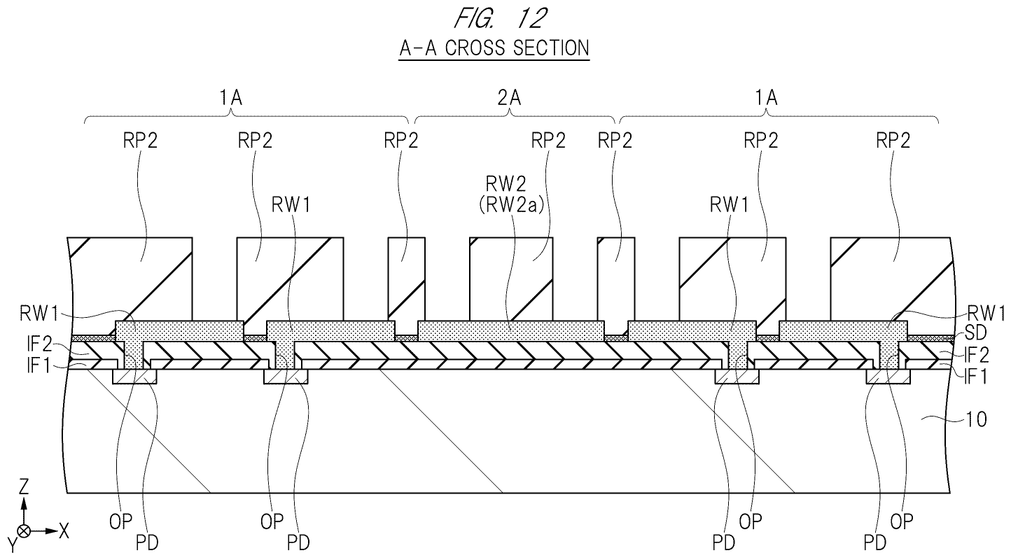

As shown in FIG. 11, the redistribution wiring RW1 electrically connected to the pad electrode PD1 is formed in the opening OP and on the insulating film IF2, and the redistribution wiring RW2 is formed on the insulating film IF2. Specifically, by the electroplating method, the redistribution wiring RW1 and the redistribution wiring RW2 are formed on the seed layer SD exposed from the resist pattern RP1. Thereafter, the resist pattern RP1 is removed by, for example, dissolution using stripping solution.

In the following description, the seed layer SD covered with the redistribution wiring RW1 and the redistribution wiring RW2 will be described as a part of the redistribution wiring RW1 and the redistribution wiring RW2, and illustration thereof will be omitted.

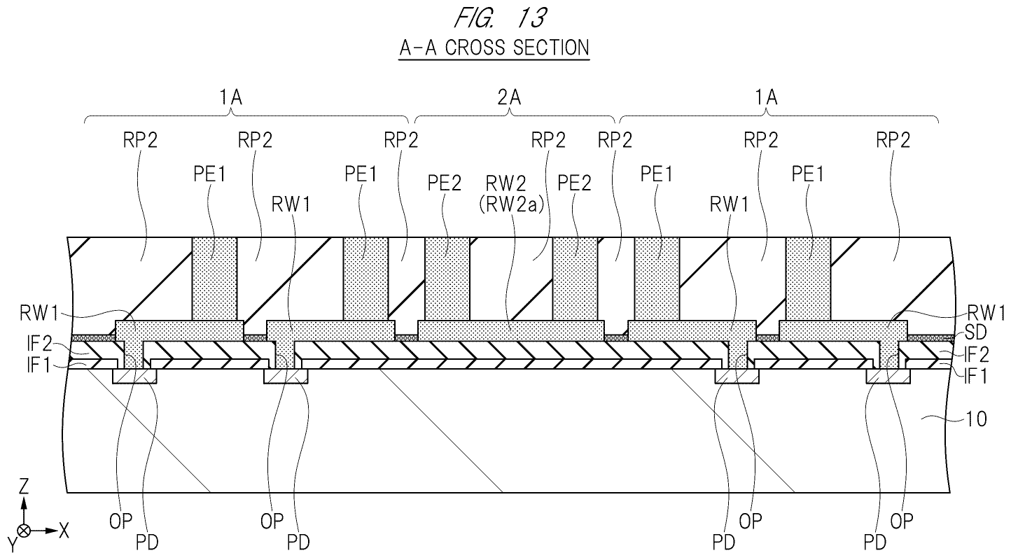

As shown in FIG. 12, a resist pattern RP2 having a pattern that opens at least a part of each of the redistribution wiring RW1 and the redistribution wiring RW2 is formed on the upper surfaces of the seed layer SD, the redistribution wiring RW1, and the redistribution wiring RW2. The resist pattern RP2 is formed by forming a resist film by the coating method and patterning the first resist film by selectively performing exposure process to the resist film.

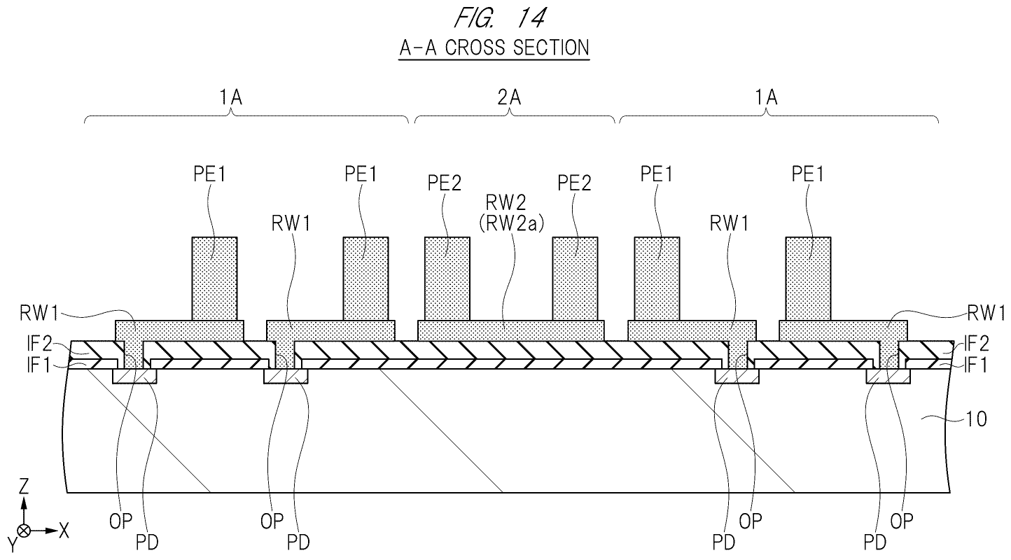

As shown in FIG. 13, the columnar electrode PE1 having a thickness larger than that of the redistribution wiring RW1 is formed on the redistribution wiring RW1, and a plurality of redistribution wirings RW2 each having a thickness larger than that of the redistribution wiring RW2 are formed on the redistribution wiring RW2. Specifically, by the electrolytic plating method, the columnar electrode PE1 is formed on the redistribution wiring RW1 exposed from the resist pattern RP2, and the columnar electrode PE2 is formed on the redistribution wiring RW2 exposed from the resist pattern RP2.

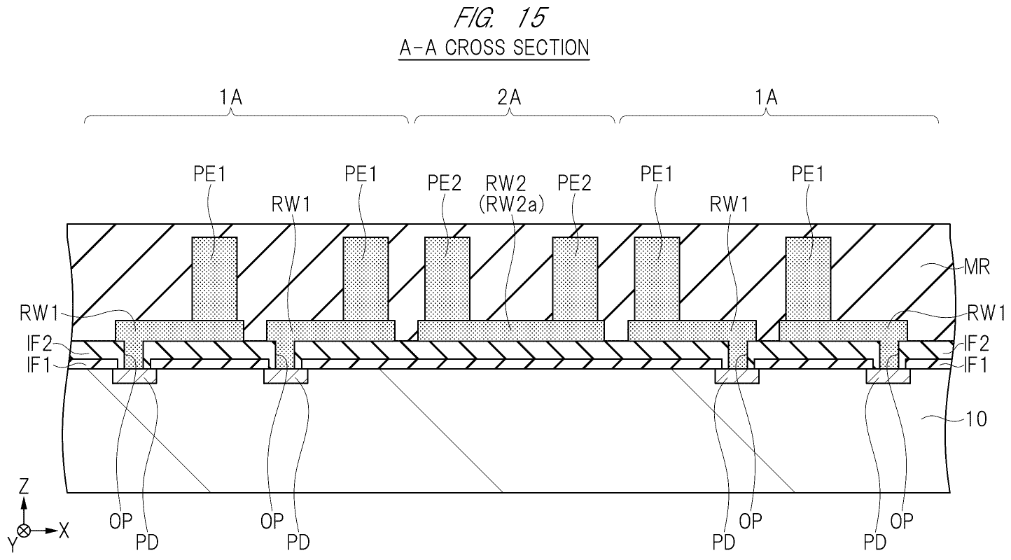

As shown in FIG. 14, the resist pattern RP2 is removed by, for example, dissolution using a stripping solution. Next, a wet etching process is performed to the seed layer SD remaining on the insulating film IF2. As a result, the seed layer SD exposed from the redistribution wiring RW1 and the redistribution wiring RW2 is removed.

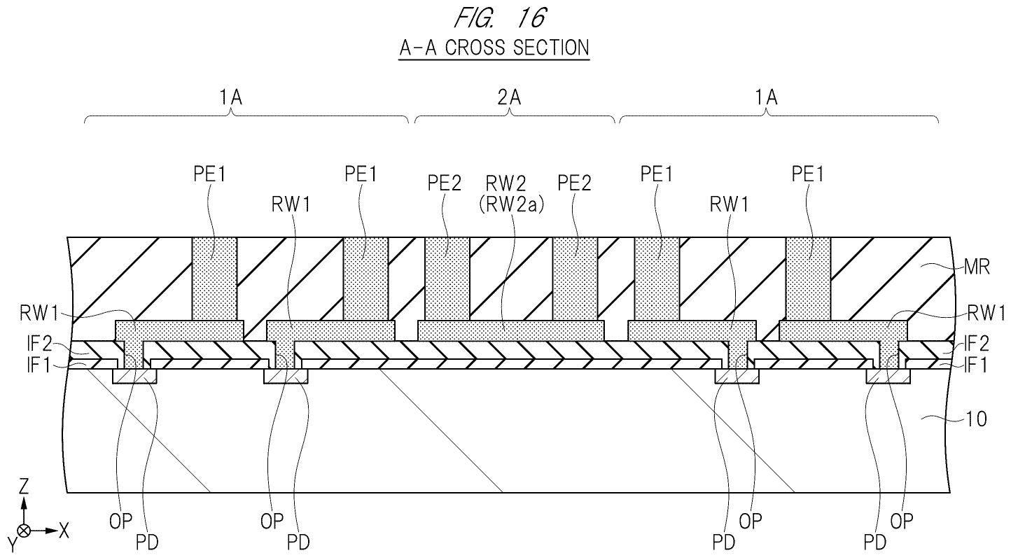

As shown in FIG. 15, the redistribution wiring RW1, the redistribution wiring RW2, the columnar electrode PE1, and the columnar electrode PE2 are sealed with the sealing resin MR on the insulating film IF2 so as to cover the upper surfaces of the columnar electrode PE1 and the columnar electrode PE2. The sealing resin MR is formed by, for example, the screen printing method. Furthermore, the sealing resin MR is formed up to a position of about 50 to 100 μm from the upper surfaces of the columnar electrode PE1 and the columnar electrode PE2.

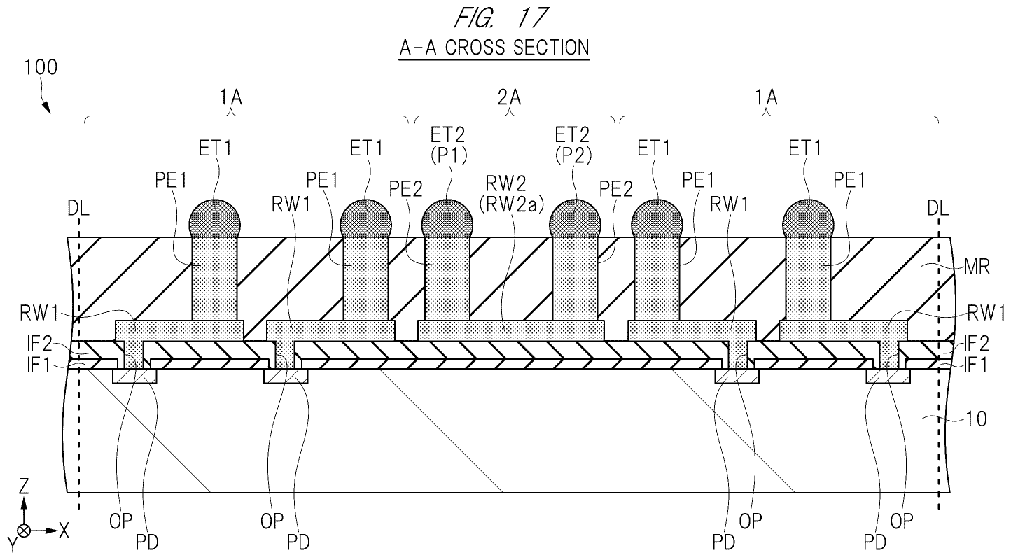

As shown in FIG. 16, the sealing resin MR is polished to expose the upper surfaces of the columnar electrode PE1 and the columnar electrode PE2 from the sealing resin MR. As a result, the upper surfaces of the columnar electrode PE1, the columnar electrode PE2, and the sealing resin MR are flattened and flush with each other.

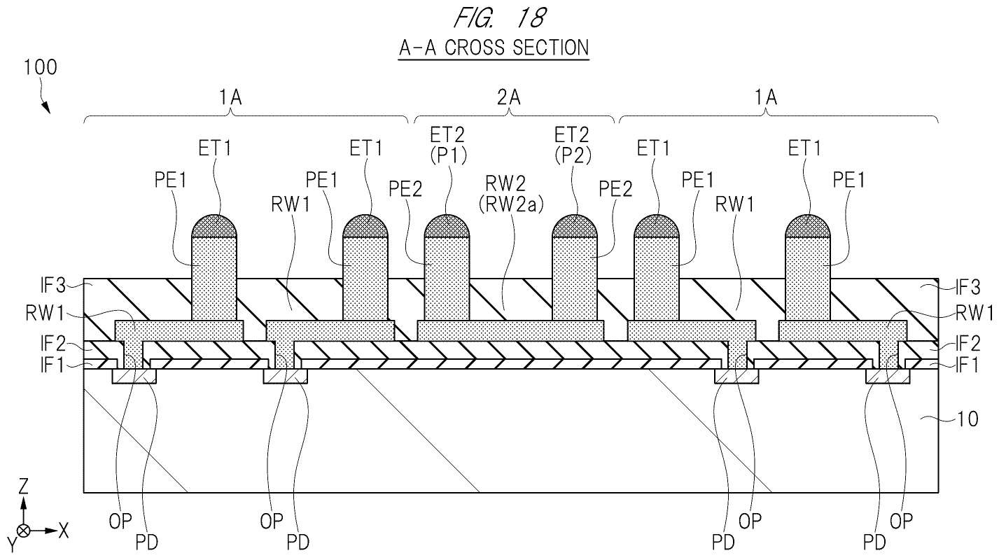

As shown in FIG. 17, the external connection terminal ET1 is formed on the upper surface of the columnar electrode PE1, and the external connection terminal ET2 is formed on the upper surface of the columnar electrode PE2. The external connection terminal ET is made of a conductive material mainly made of solder such as a solder ball. The solder ball can be formed by, for example, printing a solder paste and then performing the reflow process. Thereafter, by performing dicing along dicing lines DL, the substrate 10 is divided into pieces, and the plurality of semiconductor devices 100 shown in FIG. 2 are obtained.

Through the above process, the semiconductor device 100 according to the first embodiment is manufactured. According to the first embodiment, there is no need to add special components or special manufacturing process in order to provide the measuring circuit 20 in the semiconductor device 100. Therefore, according to the first embodiment, it is possible to suppress the manufacturing cost of the semiconductor device 100.

### Second Embodiment

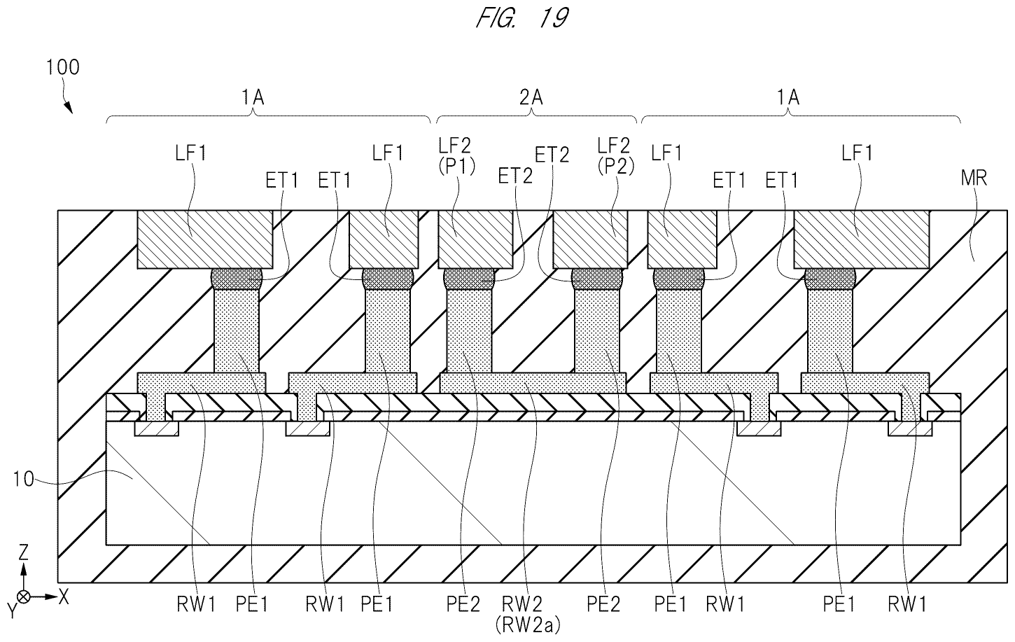

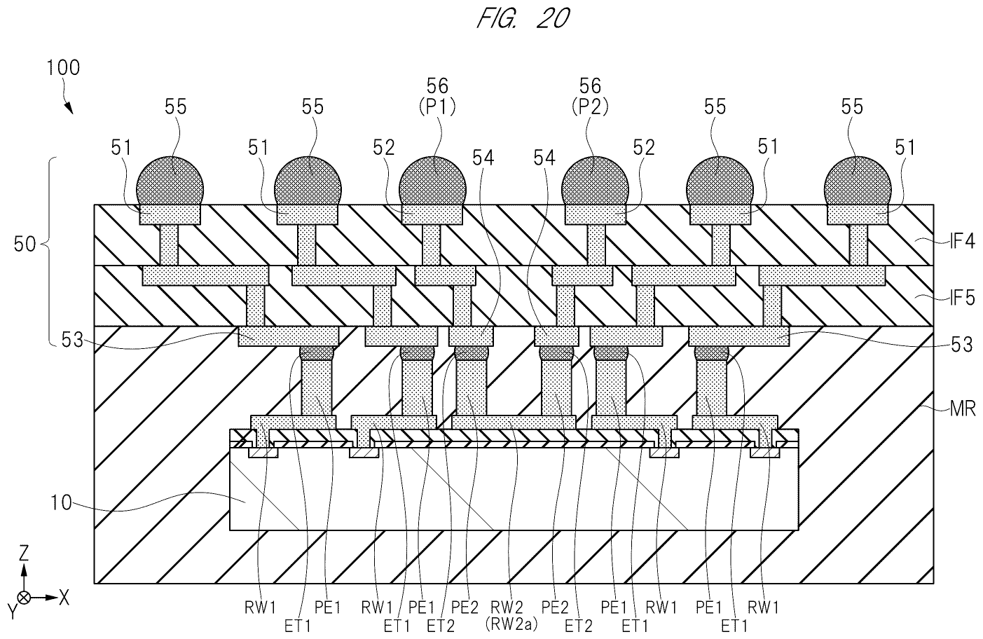

The semiconductor device 100 according to the second embodiment will be described below with reference to FIG. 18 and FIG. 19. Note that the differences from the first embodiment will be mainly described below, and descriptions that overlap with the first embodiment will be omitted.

In the first embodiment, the WLCSP structure that can be individually used as a semiconductor package has been described as an example. In the second embodiment, the case where the substrate 10 on which the redistribution wirings RW1 and RW2 are formed is mounted on a lead frame or a wiring board will be described as an example.

As shown in FIG. 18, the columnar electrode PE1 is formed on the redistribution wiring RW1, and the columnar electrode PE2 is formed on the redistribution wiring RW2. The external connection terminal ET1 is formed on the upper surface of the columnar electrode PE1, and the external connection terminal ET2 is formed on the upper surface of the columnar electrode PE2. In the second embodiment, the external connection terminals ET1 and ET2 are made of a conductive material mainly made of solder, for example, solder plating. Since the reflow process is performed after the plating process, the solder plating is configured to have a hemispherical shape. Also, the thickness of the solder plating is about 5 to 50 μm.

In addition, an insulating film IF3 is formed on the insulating film IF2 so as to cover the redistribution wirings RW1 and RW2. The insulating film IF3 is a photosensitive polyimide film formed by, for example, the coating method. Note that the insulating film IF3 is not indispensable and may not be provided.

FIG. 19 shows the case where the QFN (Quad Flat No leaded package) structure is adopted as the mounting example in FIG. 18, and a plurality of lead terminals LF1 and LF2 formed from the lead frame are used. The lead terminal LF1 is electrically connected to the external connection terminal ET1, and the lead terminal LF2 is electrically connected to the external connection terminal ET2.

In the second embodiment, the plurality of lead terminals LF2 constitute a part of the measuring circuit 20, the start terminals P1 and P2, and the end terminals P3 and P4. Namely, two lead terminals LF2 electrically connected to one inter-terminal connection portion RW2a among the plurality of lead terminals LF2 constitute the start terminal P1 and the start terminal P2, and two lead terminals LF2 electrically connected to the other inter-terminal connection portion RW2a among the plurality of lead terminals LF2 constitute the end terminal P3 and the end terminal P4.

Also, the two inter-terminal connection portions RW2a, the plurality of columnar electrodes PE2, and the plurality of external connection terminals ET2 constitute electrical paths that connect the resistance value measuring portion RW2b and the start terminals P1 and P2 and connect the resistance value measuring portion RW2b and the end terminals P3 and P4.

In addition, the sealing resin MR seals the redistribution wiring RW1, the redistribution wiring RW2, the plurality of external connection terminals ET1, the plurality of external connection terminals ET2, the plurality of lead terminals LF1, the plurality of lead terminals LF2, and the substrate 10 so as to expose the upper surfaces of the plurality of lead terminals LF1 and the plurality of lead terminals LF2.

In the second embodiment as well, by connecting the resistance measuring device 30 to the plurality of lead terminals LF2 (the start terminal P1, the start terminal P2, the end terminal P3, and the end terminal P4), the resistance value R₀ of the resistance value measuring portion RW2b can be measured.

### (First Modification)

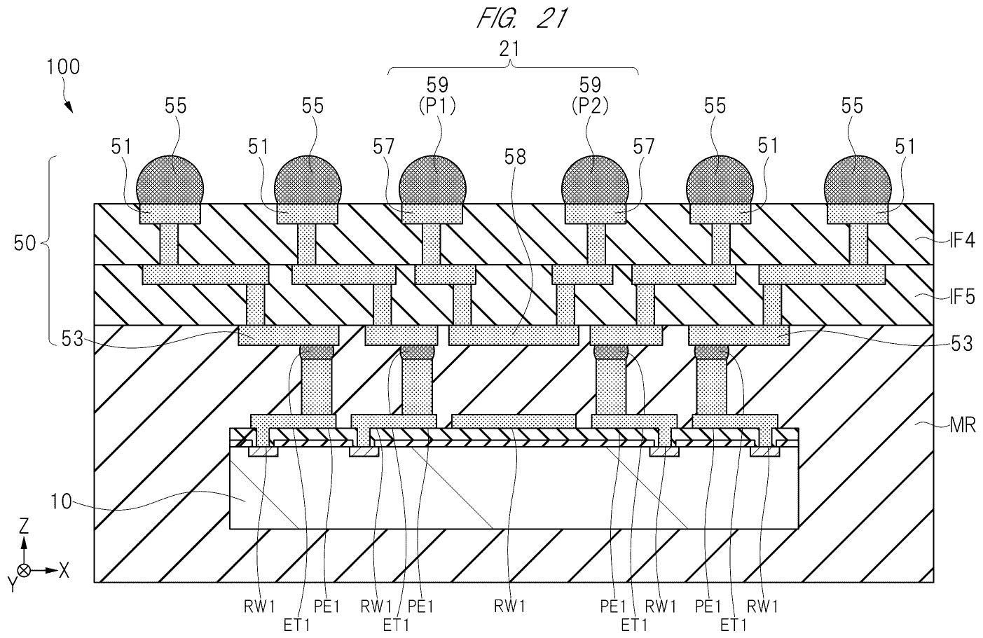

Another mounting example according to the second embodiment will be described below with reference to FIG. 20. FIG. 20 shows a mounting example using, for example, a wiring board such as a printed wiring board or a coreless substrate.

Note that other electronic components may be mounted on a coreless substrate 50 other than the semiconductor chip provided with the substrate 10. A semiconductor module in such a case will be treated as the semiconductor device 100 in a second modification.

The coreless substrate 50 has a front surface and a back surface and has a structure in which resin layers and wiring layers are alternately stacked. The coreless substrate 50 mainly includes a resin layer IF4, a resin layer IF5, a plurality of front surface wirings 51, a plurality of front surface wirings 52, a plurality of back surface wirings 53, a plurality of back surface wirings 54, a plurality of external connection terminals 55, and a plurality of external connection terminals 56.

The front surface wirings 51 and 52 and the back surface wirings 53 and 54 are made of, for example, a conductive material mainly made of copper, and are formed by, for example, the plating method. The plurality of redistribution wirings RW1 and RW2, the columnar electrodes PE1 and PE2, the plurality of external connection terminals ET1 and ET2, the plurality of back surface wirings 53 and 54, and the substrate 10 are sealed with the sealing resin MR. The resin layers IF4 and IF5 are made of, for example, a resin material such as an epoxy resin. Note that solder resists that cover a part of the front surface wirings 51 and 52 and the back surface wirings 53 and 54 are provided on the resin layers IF4 and IF5, but the illustration thereof will be omitted here.

The plurality of front surface wirings 51 and the plurality of front surface wirings 52 are formed on the front surface side of the coreless substrate 50. The plurality of back surface wirings 53 and the plurality of back surface wirings 54 are formed on the back surface side of the coreless substrate 50. The plurality of back surface wirings 53 are electrically connected to the plurality of front surface wirings 51 through other wirings and conductors such as vias formed in the coreless substrate 50. The plurality of back surface wirings 54 are electrically connected to the plurality of front surface wirings 52 through other wirings and conductors such as vias formed in the coreless substrate 50.

The plurality of external connection terminals 55 are formed on the plurality of front surface wirings 51 and are electrically connected to the plurality of front surface wirings 51. The plurality of external connection terminals 56 are formed on the plurality of front surface wirings 52 and are electrically connected to the plurality of front surface wirings 52.

The plurality of front surface wirings 52, the plurality of back surface wirings 54, and the plurality of external connection terminals 56 are electrically isolated from the plurality of front surface wirings 51, the plurality of back surface wirings 53, and the plurality of external connection terminals 55. The plurality of back surface wirings 53 are electrically connected to the plurality of external connection terminals ET1, and the plurality of back surface wirings 54 are electrically connected to the plurality of external connection terminals ET2. The plurality of front surface wirings 51, the plurality of back surface wirings 53, and the plurality of external connection terminals 55 are used for the electrical connection to an integrated circuit formed inside a semiconductor chip such as the integrated circuit of the substrate 10.

In the first modification, the plurality of front surface wirings 52, the plurality of back surface wirings 54, and the plurality of external connection terminals 56 also constitute a part of the measuring circuit 20, and the plurality of external connection terminals 56 constitute the start terminal P1, the start terminal P2, the end terminal P3, and the end terminal P4. Namely, two external connection terminals 56 electrically connected to one inter-terminal connection portion RW2a among the plurality of external connection terminals 56 constitute the start terminal P1 and the start terminal P2, and other two external connection terminals 56 electrically connected to the other inter-terminal connection portion RW2a among the plurality of external connection terminals 56 constitute the end terminal P3 and the end terminal P4.

Also, the two inter-terminal connection portions RW2a, the plurality of columnar electrodes PE2, the plurality of external connection terminals ET2, the plurality of front surface wirings 52, and the plurality of back surface wirings 54 constitute electrical paths that connect the resistance value measuring portion RW2b and the start terminals P1 and P2 and connect the resistance value measuring portion RW2b and the end terminals P3 and P4.

In the first modification as well, by connecting the resistance measuring device 30 to the plurality of external connection terminals 56 (the start terminal P1, the start terminal P2, the end terminal P3, and the end terminal P4), the resistance value R0 of the resistance value measuring portion RW2b can be measured.

Also, in the first modification, the distance (pitch) between each of the plurality of external connection terminals 56 is larger than the distance (pitch) between each of the plurality of external connection terminals ET2. For example, there is a fear that defects such as short circuits may occur if the pitch of the plurality of external connection terminals ET2 is small when mounting the semiconductor device 100 on a motherboard or the like. Such a fear can be eliminated by applying the mounting example described in the first modification to increase the pitch of the plurality of external connection terminals 56.

### (Second Modification)

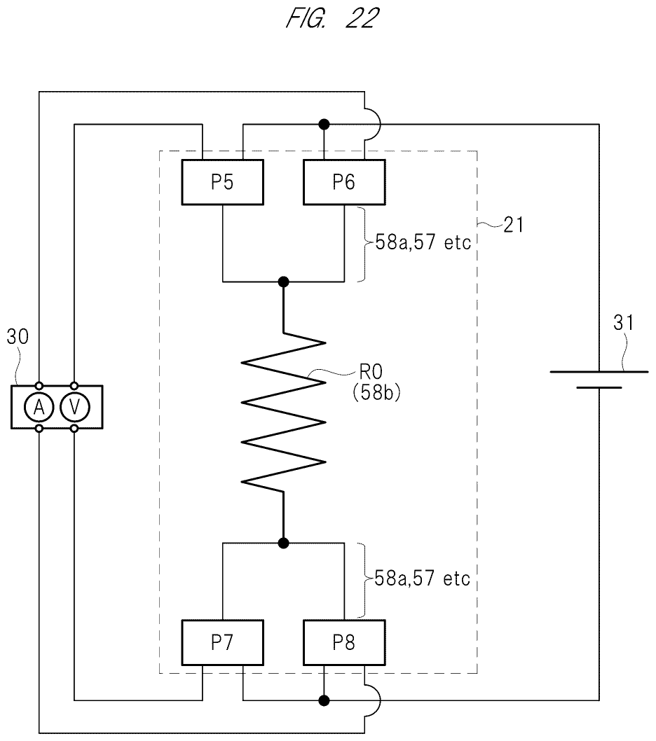

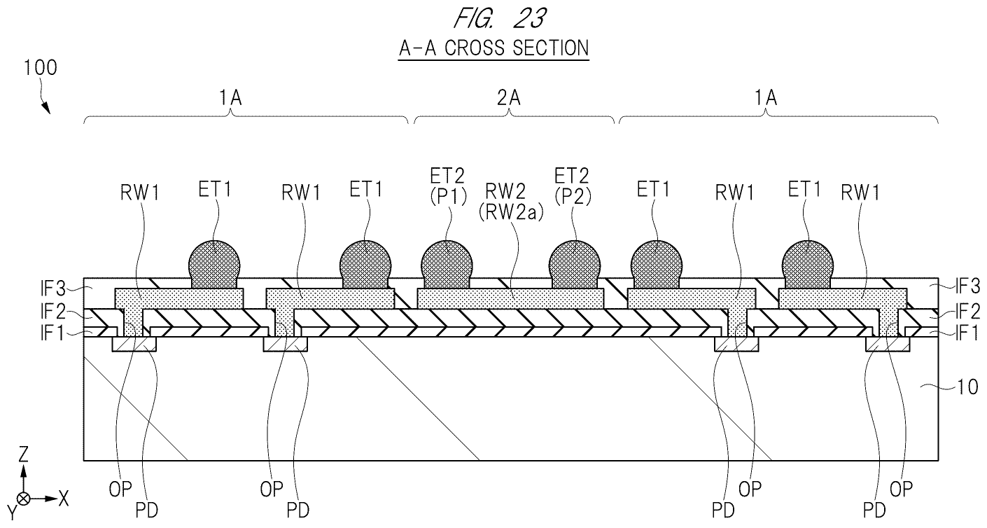

Another mounting example according to the second embodiment will be described below with reference to FIG. 21 and FIG. 22. In the second modification as well, the coreless substrate 50 is used like the first modification, and the structure of the second modification is almost the same as that of the first modification. However, in the second modification, the measuring circuit 20 using the redistribution wiring RW2 is not provided as shown in FIG. 21, and another measuring circuit 21 for measuring a resistance value different from the measuring circuit 20 is provided in the coreless substrate 50.

The measuring circuit 21 like this is composed of a plurality of front surface wirings 57, a back surface wiring 58, and a plurality of external connection terminals 59. The plurality of front surface wirings 57, the back surface wiring 58, and the plurality of external connection terminals 59 are formed in the region different from those of the plurality of front surface wirings 51, the plurality of back surface wirings 53, and the plurality of external connection terminals 55, and are electrically isolated from them.

FIG. 22 shows an equivalent circuit of the measuring circuit 21. Though not shown in detail, the back surface wiring 58 has the same function as the redistribution wiring RW2. The back surface wiring 58 has two inter-terminal connection portions 58a and a resistance value measuring portion 58b that connects the two inter-terminal connection portions 58a. Two external connection terminals among the plurality of external connection terminals 59 are electrically connected to one inter-terminal connection portion 58a and constitute a start terminal P5 and a start terminal P6. Other two external connection terminals 59 among the plurality of external connection terminals 59 are electrically connected to the other inter-terminal connection portion 58a and constitute an end terminal P7 and an end terminal P8.

In the second modification, the two inter-terminal connection portions 58a, the plurality of front surface wirings 57, and other wirings and conductors such as vias formed inside the coreless substrate 50 constitute electrical paths that connect the resistance value measuring portion 58b and the start terminals P5 and P6 and connect the resistance value measuring portion 58b and the end terminals P7 and P8.

By electrically connecting the resistance measuring device 30 to the start terminal P5, the start terminal P6, the end terminal P7, and the end terminal P8, the resistance value R₀ of the resistance value measuring portion 58b can be measured. Then, by using the same means as that in the flowchart in FIG. 4, the temperature of the resistance value measuring portion 58b can be calculated from the measured resistance value R0 of the resistance value measuring portion 58b.

By using the coreless substrate 50 of the second modification, the temperature inside the semiconductor device 100 can be measured even if there is no measuring circuit 20 using the redistribution wiring RW2. Therefore, the second modification can be applied to, for example, the semiconductor device in which the redistribution wirings RW1 and RW2 and the like are not formed and bump electrodes are formed directly on the pad electrodes PD. Accordingly, even for single semiconductor chips that are difficult to procure or process in wafer state or semiconductor chips that use special materials such as compound semiconductors, the temperature inside the semiconductor chip can be measured by applying the second modification.

Further, it is also possible to provide the measuring circuit 20 using the redistribution wiring RW2 as in the first modification (FIG. 20) and to provide the measuring circuit 21 of the second modification at a position different from the measuring circuit 20. In that case, temperatures at different locations inside the semiconductor device 100 can be measured simultaneously. In other words, according to the second modification, the circuit for measuring the temperature inside the semiconductor device 100 may be only the measuring circuit 21 in the coreless substrate 50, or the measuring circuit 21 and the measuring circuit 20 using the redistribution wiring RW2 may be used together.

### Third Embodiment

The semiconductor device 100 according to the third embodiment will be described below with reference to FIG. 23. Note that the differences from the first embodiment will be mainly described below, and descriptions that overlap with the first embodiment will be omitted.

In the third embodiment, the columnar electrodes PEL and PE2 are not formed, the external connection terminal ET1 is formed directly on the redistribution wiring RW1, and the plurality of external connection terminals ET2 are each formed directly on the redistribution wiring RW2.

The insulating film IF3 is formed on the insulating film IF2 so as to cover the redistribution wirings RW1 and RW2. The insulating film IF3 is a photosensitive polyimide film formed by, for example, the coating method. A plurality of openings are provided in a part of the insulating film IF3, and the external connection terminals ET1 and ET2 are formed in the regions exposed from the plurality of openings. The external connection terminals ET1 and ET2 in the third embodiment are made of a conductive material mainly made of solder, and are composed of, for example, stacked films of solder bumps and metal films formed under the solder bumps. The diameter of the solder bumps is about 50 to 250 μm.

In the third embodiment, the redistribution wiring RW2 and the plurality of external connection terminals ET2 constitute the measuring circuit 20. In the third embodiment as well, by connecting the resistance measuring device 30 to the plurality of external connection terminals ET2 (the start terminal P1, the start terminal P2, the end terminal P3, and the end terminal P4), the resistance value R₀ of the resistance value measuring portion RW2b can be measured.

Note that the structure provided with the columnar electrodes PE1 and PE2 shown in FIG. 18 is used in each of the mounting examples of the second embodiment, the first modification, and the second modification, but the structure of the third embodiment may be applied to the second embodiment, the first modification, and the second modification.

In the foregoing, the present invention has been specifically described based on the embodiments, but the present invention is not limited to these embodiments, and can be modified in various ways within the range not departing from the gist thereof.

1. A semiconductor device comprising:
a substrate having an integrated circuit formed therein and having a pad electrode formed on an upper surface thereof and electrically connected to the integrated circuit;
an insulating film formed on the upper surface of the substrate so as to cover the pad electrode;
an opening formed in the insulating film so as to reach an upper surface of the pad electrode;
a first redistribution wiring formed in the opening and on the insulating film and electrically connected to the pad electrode;
a first external connection terminal formed on the first redistribution wiring and electrically connected to the first redistribution wiring;
a second redistribution wiring formed on the insulating film and electrically isolated from the first redistribution wiring, the pad electrode, and the integrated circuit; and
a plurality of second external connection terminals formed on the second redistribution wiring and electrically connected to the second redistribution wiring,
wherein the second redistribution wiring and the plurality of second external connection terminals constitute a first measuring circuit for measuring a resistance value.

2. The semiconductor device according to claim 1,
wherein the second redistribution wiring includes a first inter-terminal connection portion, a second inter-terminal connection portion, and a first resistance value measuring portion that connects the first inter-terminal connection portion and the second inter-terminal connection portion,
wherein two second external connection terminals among the plurality of second external connection terminals are electrically connected to the first inter-terminal connection portion and constitute a first start terminal and a second start terminal,
wherein other two second external connection terminals among the plurality of second external connection terminals are electrically connected to the second inter-terminal connection portion and constitute a third end terminal and a fourth end terminal, and
wherein a resistance value of the first resistance value measuring portion can be measured by electrically connecting a resistance measuring device to the first start terminal, the second start terminal, the third end terminal, and the fourth end terminal.

3. The semiconductor device according to claim 2,
wherein a temperature of the first resistance value measuring portion can be calculated from the resistance value of the first resistance value measuring portion measured by the resistance measuring device with reference to data showing a correlation between the resistance value of the first resistance value measuring portion and the temperature of the first resistance value measuring portion.

4. The semiconductor device according to claim 2,
wherein when a resistance value between the first start terminal and the third end terminal is R₁₃, a resistance value between the second start terminal and the fourth end terminal is R₂₄, a resistance value between the first start terminal and the second start terminal is R₁₂, and a resistance value between the third end terminal and the fourth end terminal is R₃₄, the resistance value of the first resistance value measuring portion can be obtained by {(R₁₃+R₂₄)−(R₁₂+R₃₄)}/2.

5. The semiconductor device according to claim 1, further comprising:
a first columnar electrode formed on the first redistribution wiring and electrically connected to the first redistribution wiring and the first external connection terminal;
a plurality of second columnar electrodes formed on the second redistribution wiring and electrically connected to the second redistribution wiring and the plurality of second external connection terminals; and
a sealing resin configured to seal the first redistribution wiring, the second redistribution wiring, the first columnar electrode, and the plurality of second columnar electrodes so as to expose upper surfaces of the first columnar electrode and the plurality of second columnar electrodes,
wherein the first external connection terminal is formed on the upper surface of the first columnar electrode, and
wherein the plurality of second external connection terminals are formed on the upper surfaces of the plurality of second columnar electrodes, respectively.

6. The semiconductor device according to claim 1,
wherein the first external connection terminal is formed directly on the first redistribution wiring, and
wherein the plurality of second external connection terminals are each formed directly on the second redistribution wiring.

7. The semiconductor device according to claim 1, further comprising:
a first lead terminal electrically connected to the first external connection terminal;
a plurality of second lead terminals electrically connected to the plurality of second external connection terminals; and
a sealing resin configured to seal the first redistribution wiring, the second redistribution wiring, the first external connection terminal, the plurality of second external connection terminals, the first lead terminal, the plurality of second lead terminals, and the substrate so as to expose upper surfaces of the first lead terminal and the plurality of second lead terminals,
wherein the second redistribution wiring, the plurality of second external connection terminals, and the plurality of second lead terminals constitute the first measuring circuit.

8. The semiconductor device according to claim 7,
wherein the second redistribution wiring includes a first inter-terminal connection portion, a second inter-terminal connection portion, and a first resistance value measuring portion that connects the first inter-terminal connection portion and the second inter-terminal connection portion,
wherein two second external connection terminals among the plurality of second external connection terminals are electrically connected to the first inter-terminal connection portion,
wherein other two second external connection terminals among the plurality of second external connection terminals are electrically connected to the second inter-terminal connection portion,
wherein two second lead terminals electrically connected to the first inter-terminal connection portion among the plurality of second lead terminals constitute a first start terminal and a second start terminal,
wherein other two second lead terminals electrically connected to the second inter-terminal connection portion among the plurality of second lead terminals constitute a third end terminal and a fourth end terminal, and
wherein a resistance value of the first resistance value measuring portion can be measured by electrically connecting a resistance measuring device to the first start terminal, the second start terminal, the third end terminal, and the fourth end terminal.

9. The semiconductor device according to claim 1, further comprising a wiring board having a front surface and a back surface,
wherein the wiring board includes:
a first front surface wiring and a plurality of second front surface wirings formed on a front surface side of the wiring board;
a first back surface wiring formed on a back surface side of the wiring board and electrically connected to the first front surface wiring;
a plurality of second back surface wirings formed on the back surface side of the wiring board and electrically connected to the plurality of second front surface wirings;
a third external connection terminal formed on the first front surface wiring and electrically connected to the first front surface wiring; and
a plurality of fourth external connection terminals formed on the plurality of second front surface wirings and electrically connected to the plurality of second front surface wirings,
wherein the first redistribution wiring, the second redistribution wiring, the first external connection terminal, the plurality of second external connection terminals, the first back surface wiring, the plurality of second back surface wirings, and the substrate are sealed with a sealing resin,
wherein the plurality of second front surface wirings, the plurality of second back surface wirings, and the plurality of fourth external connection terminals are electrically isolated from the first front surface wiring, the first back surface wiring, and the third external connection terminal,
wherein the first back surface wiring is electrically connected to the first external connection terminal,
wherein the plurality of second back surface wirings are electrically connected to the plurality of second external connection terminals, and
wherein the second redistribution wiring, the plurality of second external connection terminals, the plurality of second front surface wirings, the plurality of second back surface wirings, and the plurality of fourth external connection terminals constitute the first measuring circuit.

10. The semiconductor device according to claim 9,
wherein the second redistribution wiring includes a first inter-terminal connection portion, a second inter-terminal connection portion, and a first resistance value measuring portion that connects the first inter-terminal connection portion and the second inter-terminal connection portion,
wherein two second external connection terminals among the plurality of second external connection terminals are electrically connected to the first inter-terminal connection portion,
wherein other two second external connection terminals among the plurality of second external connection terminals are electrically connected to the second inter-terminal connection portion,
wherein two fourth external connection terminals electrically connected to the first inter-terminal connection portion among the plurality of fourth external connection terminals constitute a first start terminal and a second start terminal,
wherein other two fourth external connection terminals electrically connected to the second inter-terminal connection portion among the plurality of fourth external connection terminals constitute a third end terminal and a fourth end terminal, and
wherein a resistance value of the first resistance value measuring portion can be measured by electrically connecting a resistance measuring device to the first start terminal, the second start terminal, the third end terminal, and the fourth end terminal.

11. The semiconductor device according to claim 9,
wherein a distance between each of the plurality of fourth external connection terminals is larger than a distance between each of the plurality of second external connection terminals.

12. The semiconductor device according to claim 9,
wherein the wiring board further includes:
a plurality of third front surface wirings formed on the front surface side of the wiring board;
a third back surface wiring formed on the back surface side of the wiring board and electrically connected to the plurality of third front surface wirings; and
a plurality of fifth external connection terminals formed on the plurality of third front surface wirings and electrically connected to the plurality of third front surface wirings,
wherein the plurality of third front surface wirings, the third back surface wiring, and the plurality of fifth external connection terminals are electrically isolated from the first front surface wiring, the first back surface wiring, the third external connection terminal, the plurality of second front surface wirings, the plurality of second back surface wirings, and the plurality of fourth external connection terminals, and
wherein the plurality of third front surface wirings, the third back surface wiring, and the plurality of fifth external connection terminals constitute a second measuring circuit for measuring a resistance value different from the first measuring circuit.

13. The semiconductor device according to claim 12,
wherein the third back surface wiring includes a third inter-terminal connection portion, a fourth inter-terminal connection portion, and a second resistance value measuring portion that connects the third inter-terminal connection portion and the fourth inter-terminal connection portion,
wherein two fifth external connection terminals among the plurality of fifth external connection terminals are electrically connected to the third inter-terminal connection portion and constitute a fifth start terminal and a sixth start terminal,
wherein other two fifth external connection terminals among the plurality of fifth external connection terminals are electrically connected to the fourth inter-terminal connection portion and constitute a seventh end terminal and an eighth end terminal, and
wherein a resistance value of the second resistance value measuring portion can be measured by electrically connecting a resistance measuring device to the fifth start terminal, the sixth start terminal, the seventh end terminal, and the eighth end terminal.

14. A wiring board having a front surface and a back surface, the wiring board comprising:
a first front surface wiring and a plurality of third front surface wirings formed on a front surface side of the wiring board;
a first back surface wiring formed on a back surface side of the wiring board and electrically connected to the first front surface wiring;
a third back surface wiring formed on the back surface side of the wiring board and electrically connected to the plurality of third front surface wirings;
a third external connection terminal formed on the first front surface wiring and electrically connected to the first front surface wiring; and
a plurality of fifth external connection terminals formed on the plurality of third front surface wirings and electrically connected to the plurality of third front surface wirings,
wherein the plurality of third front surface wirings, the third back surface wiring, and the plurality of fifth external connection terminals are electrically isolated from the first front surface wiring, the first back surface wiring, and the third external connection terminal,
wherein the first front surface wiring, the first back surface wiring, and the third external connection terminal are used for electrical connection to an integrated circuit formed inside a semiconductor chip, and
wherein the plurality of third front surface wirings, the third back surface wiring, and the plurality of fifth external connection terminals constitute a second measuring circuit for measuring a resistance value.

15. The wiring board according to claim 14,
wherein the third back surface wiring includes a third inter-terminal connection portion, a fourth inter-terminal connection portion, and a second resistance value measuring portion that connects the third inter-terminal connection portion and the fourth inter-terminal connection portion,
wherein two fifth external connection terminals among the plurality of fifth external connection terminals are electrically connected to the third inter-terminal connection portion and constitute a fifth start terminal and a sixth start terminal,
wherein other two fifth external connection terminals among the plurality of fifth external connection terminals are electrically connected to the fourth inter-terminal connection portion and constitute a seventh end terminal and an eighth end terminal, and
wherein a resistance value of the second resistance value measuring portion can be measured by electrically connecting a resistance measuring device to the fifth start terminal, the sixth start terminal, the seventh end terminal, and the eighth end terminal.
